(19) United States
(12) Patent Application Publication
(10) Pub. No.: US 2017/0175249 A1
(43) Pub. Date: Jun. 22, 2017

(54) THIN METAL FILM SUBSTRATE AND METHOD FOR PREPARING THE SAME

(71) Applicant: Korea Institute of Machinery & Materials, Yuseong-Gu Daejeon (KR)

(72) Inventors: Jung Heum Yun, Gimhae-si, Gyeongsangnam-do (KR); Gun Hwan Lee, Pyeongtaek-si, Gyeonggi-do (KR); Myung Kwan Song, Jung-gu, Ulsan (KR); Sung Hun Lee, Changwon-si, Gyeongsangnam-do (KR); Guo Qing Zhao, Gimhae-si, Gyeongsangnam-do (KR)

(21) Appl. No.: 15/122,064

(22) PCT Filed: May 13, 2016
(86) PCT No.: PCT/KR2016/005124

§ 371 Date: Aug. 26, 2016

(30) Foreign Application Priority Data
May 15, 2015 (KR) 10-2015-0067837
May 13, 2016 (KR) 10-2016-0059030

(51) Int. Cl. C23C 14/18; C23C 14/20; C23C 14/34; C23C 14/24

(52) U.S. Cl. CPC C23C 14/18; C23C 14/24; C23C 14/20; C23C 14/3457

(57) ABSTRACT

The present disclosure related to a thin metal film substrate and a method for preparing the same and more particularly, to a thin metal film substrate including a substrate; and a thin metal film comprising Ag or an Ag alloy formed on the substrate, wherein the thin metal film is formed to have preferred orientation corresponding to the preferred orientation of the substrate during the initial growth. The thin metal film substrate according to an example grows in a 2D continuous thin film from the initial growth to provide excellent light transmittance and conductivity.

### CROSS REFERENCE TO RELATED APPLICATION

This application claims the benefit under 35 U.S.C. §119(a) of Korean Patent Application No. 10-2015-0067837 filed on May 15, 2015 and Korean Patent Application No. 10-2016-0059030 filed on May 13, 2016 in the Korean Intellectual Property Office, the entire disclosure of which is incorporated herein by reference for all purposes.

### BACKGROUND

1. Technical Field

The following description relates to a thin metal film substrate and a method for preparing the same.

2. Description of Related Art

A thin metal film made of Ag has high conductivity and high light transmittance from high visible light region to low infrared region and has been thus used for a transparent conductive film, an optical sensor, a smart window and the like.

Since it is needed to have superior electrical conductivity with controlled light absorption and reflection to be used for such applications, a technology for forming continuous thin metal films in a range of several tens of nm to several nm on various inorganic substrates including a non-conductor (insulator), a semiconductor and a conductor to meet the demands.

However, a metal grows initially in 3D particles, instead of in a 2D continuous thin film on a substrate due to its low wettability. This initial growth behavior is for higher coherence between the metals rather than coherence between the substrate and the metal. This growth behavior appears prominently in noble metals such as Au, Pt, Ag and the like and partially in high conductive metals such as Cu, Ni, Al and the like.

Thus, it is difficult to meet the requirements of a continuous 2D thin film due to this growth behavior from the beginning and also needed to have a certain thickness to form the continuous thin film.

The followings have been used in order to control this growth behavior of the metal: (1) use of a substrate having high wettability and coherence with a metal; (2) forming a seed thin metal film on a substrate before depositing a metal; (3) controlling deposition rate and temperature; (4) use of a metal doped with trace amount of another metal such as Al, Cu or the like; and (5) doping a metal with trace amount of oxygen, etc.

As such, these conventional methods have been limited to control/modify the surface of the substrate to prevent the 3D growth behavior of the metal.

On the other hand, when trace amount of a different metal from Ag is used for doping, this different metal can deteriorate properties due to its lower conductivity and light transmittance than Ag. When trace amount of oxygen is used for doping, it is difficult to provide uniform properties over a large area.

KR 10-2012-0097451 discloses a technology for providing excellent conductivity and light transmittance by controlling a composition of zinc oxide-based transparent conductive thin metal film.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

As object of the present disclosure is to provide a thin metal film substrate on which a thin metal film having excellent light transmittance and conductivity is able to be formed in a 2D continuous thin film from the beginning.

Another object of the present disclosure is to provide a method for preparing a thin metal film substrate on which a thin metal film having excellent light transmittance and conductivity is able to be formed in a 2D continuous thin film from the beginning.

According to an aspect of the present disclosure, there is provided a thin metal film substrate including a substrate; and a thin metal film comprising Ag or an Ag alloy formed on the substrate, wherein a ratio of (111) face of the thin metal film to the whole crystal faces decreases as a thickness of the thin metal film increases.

According to another aspect of the present disclosure, there is provided a thin metal film substrate including a substrate; and a thin metal film comprising Ag or an Ag alloy formed on the substrate, wherein the thin metal film is formed by a physical vapor deposition and a process gas includes N₂.

According to an embodiment of the present disclosure, degree of preferred orientation (p (111)) of the (111) face of the thin metal film may be 1.6 or more.

According to an embodiment of the present disclosure, l(111)/l(200) of the thin metal film may be 10 or more.

According to an embodiment of the present disclosure, when the thickness of the thin metal film is 10 nm or more, degree of preferred orientation (p (111)) of the (111) face of the thin metal film may be 1.7 or less.

According to an embodiment of the present disclosure, when the thickness of the thin metal film is 10 nm or more, l(111)/l(200) of the thin metal film may be 12 or less.

According to an embodiment of the present disclosure, a thickness of the thin metal film may be in a range of from more than 0 nm to 40 nm.

According to an embodiment of the present disclosure, surface roughness of the thin metal film may be in a range of from more than 0 nm to. 0.8 nm.

According to an embodiment of the present disclosure, the substrate may be a transparent polymer substrate.

According to an embodiment of the present disclosure, the substrate may include conductive oxide or nitride.

According to an embodiment of the present disclosure, the thin metal film substrate may have 30 Ω/sq or less of sheet resistance.

According to an embodiment of the present disclosure, the thin metal film substrate may have 85% or more of light transmittance.

According to an embodiment of the present disclosure, the thin metal film substrate may further include an intermediate layer formed between the substrate and the thin metal film.

According to an embodiment of the present disclosure, the thin metal film substrate may further include a protecting layer formed on the thin metal film.

According to an embodiment of the present disclosure, the thin metal film may be doped with nitrogen.

According to an embodiment of the present disclosure, when a thickness of the thin metal film is 10 nm or less, nitrogen content of the thin metal film may be 20% or less.

According to an embodiment of the present disclosure, the thin metal film may be formed by a physical vapor deposition using process gases of Ar and N₂.

According to an embodiment of the present disclosure, the process gases of Ar and N₂ may be in a ratio of 45:2 to 35.

According to another aspect of the present disclosure, there is provided an article including the thin metal film substrate.

According to an embodiment of the present disclosure, the article may be a transparent electrode for displays, a polarizing plate, a transparent electrode for solar cells, a low-emission coating, a transparent electrode for heating, or a metal micro-electrode for semiconductors.

According to still another aspect of the present disclosure, there is provided a method for preparing a thin metal film substrate including preparing a substrate; and forming a thin metal film including Ag or an Ag alloy on the substrate by a physical vapor deposition, wherein a process gas of the physical vapor deposition includes N₂.

According to an embodiment of the present disclosure, the process gas of the physical vapor deposition may include Ar and N₂.

According to an embodiment of the present disclosure, the process gas of the physical vapor deposition may be in a ratio of 45:2 to 35 of Ar:N₂.

According to an embodiment of the present disclosure, a ratio of (111) face of the thin metal film to the whole crystal faces may decrease as a thickness of the thin metal film increases.

According to an embodiment of the present disclosure, when a thickness of the thin metal film is 10 nm or less, nitrogen content of the thin metal film may be 20% or less.

According to an embodiment of the present disclosure, the method may further include forming an intermediate layer formed between the substrate and the thin metal film.

According to an embodiment of the present disclosure, the method may further include forming a protecting layer formed on the thin metal film.

According to an embodiment of the present disclosure, a thin metal film substrate may be able to be formed in a 2D continuous thin film from the beginning and have excellent light transmittance and conductivity.

According to an embodiment of the present disclosure, a thin metal film substrate having excellent light transmittance and conductivity may be prepared on a large scale.

### BRIEF DESCRIPTION OF DRAWINGS

Hereinafter, the following description will be described with reference to embodiments illustrated in the accompanying drawings. To help understanding of the following description, throughout the accompanying drawings, identical reference numerals are assigned to identical elements. The elements illustrated throughout the accompanying drawings are mere examples of embodiments illustrated for the purpose of describing the following description and are not to be used to restrict the scope of the following description.

FIG. 1 is a diagram illustrating internal configuration of a thin metal film substrate according to an embodiment of the present disclosure.

FIG. 2 is a diagram illustrating internal configuration of a thin metal film substrate according to another embodiment of the present disclosure.

FIG. 3 is a flowchart illustrating a method for forming a thin metal film substrate according to an embodiment of the present disclosure.

FIG. 4 illustrates diagrams comparing growth pattern (I) of a general metal and growth pattern (II) of a metal according to an embodiment of the present disclosure.

FIG. 5 is a graph illustrating preferred orientation of a thin metal film according to an embodiment of the present disclosure depending on an amount of a process gas and a thickness of the thin metal film.

FIG. 6 is a graph illustrating degree of preferred orientation of a thin metal film according to an embodiment of the present disclosure depending on an amount of a process gas and a thickness of the thin metal film.

FIG. 7 to FIG. 9 are Pole figures illustrating Psi rocking curves relating to preferred orientation depending on an amount of a process gas and a thickness of the thin metal film.

FIG. 10 to FIG. 16 are FE-SEM images of a thin metal film according to an embodiment of the present disclosure depending on an amount of a process gas.

FIG. 17 illustrates diagrams of compositional analyses of a thin metal film substrate according to an embodiment of the present disclosure.

FIG. 18 is a graph comparing surface roughness of a thin metal film substrate according to an embodiment of the present disclosure depending on an amount of a process gas.

FIG. 19 is a graph comparing surface roughness of a thin metal film substrate according to an embodiment of the present disclosure depending on a thickness of the thin metal film substrate.

FIG. 20 is a graph comparing resistivity of a thin metal film substrate according to an embodiment of the present disclosure depending on an amount of a process gas.

FIG. 21 is a graph illustrating whether independent AgN phase is present or not in Ag(N) through 2 theta scanning of a thin metal film according to an embodiment of the present disclosure.

FIG. 22 and FIG. 23 are graphs illustrating SIMS analyses to detect residue N in Ag(N).

FIG. 24 and FIG. 25 are graphs illustrating optical transmittance of a thin metal film substrate according to an embodiment of the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

Since there can be a variety of permutations and embodiments of the following description, certain embodiments will be illustrated and described with reference to the accompanying drawings. This, however, is by no means to restrict the following description to certain embodiments, and shall be construed as including all permutations, equivalents and substitutes covered by the ideas and scope of the following description. Throughout the description of the present disclosure, when describing a certain technology is determined to evade the point of the present disclosure, the pertinent detailed description will be omitted. Unless clearly used otherwise, expressions in the singular number include a plural meaning.

The terms used in the description are intended to describe certain embodiments only, and shall by no means restrict the present disclosure. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

Throughout the description of the present disclosure, when describing a certain technology is determined to evade the point of the present disclosure, the pertinent detailed description will be omitted.

The disclosure will be described below in more detail with reference to the accompanying drawings, in which those components are rendered the same reference number that are the same or are in correspondence, regardless of the figure number, and redundant explanations are omitted.

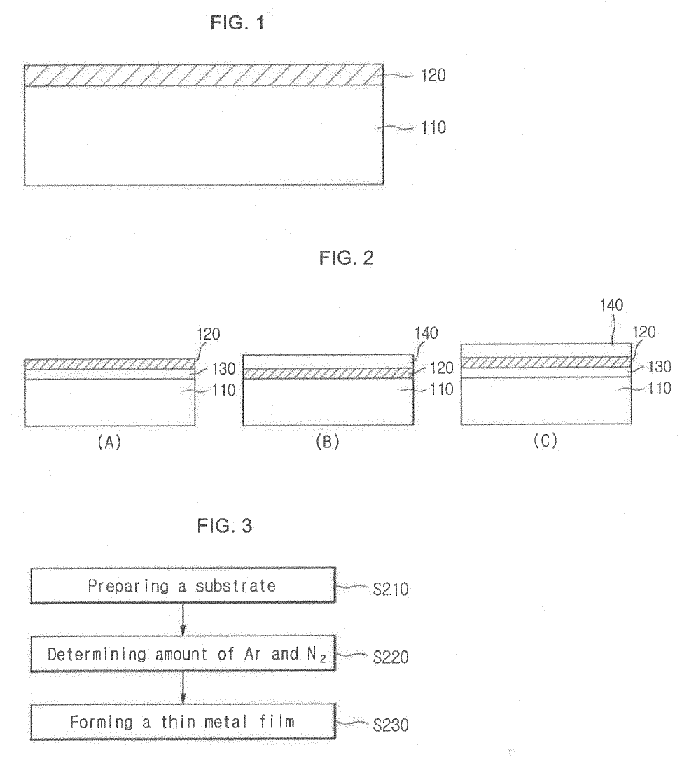

FIG. 1 is a diagram illustrating internal configuration of a thin metal film substrate according to an embodiment of the present disclosure.

Referring to FIG. 1, a thin metal film substrate according to an embodiment of the present disclosure may include a substrate 110 and a thin metal film 120.

The substrate 110 may a basic material on which the thin metal film 120 is to be formed.

The substrate 110 may include any one of a transparent polymer and glass, but it is not limited thereto. When the thin metal film substrate of the present disclosure is used as a transparent conductive film, the substrate 110 may be formed in a transparent polymer or glass layer under the thin film formed of a metal, a conductive oxide, or a conductivity nitride. Thus, when the substrate 110 is formed of the transparent polymer, it can be used for transparent flexible displays and transparent electrodes for flexible solar cells. The substrate 110 may be thus formed of a transparent polymer for transparent flexible displays including PC, PET, PES, PEN, PAR, PI and the like.

The substrate 110 may be any material if thin metal film 120 can be formed thereon. The substrate 110 may include any one of a dielectric material (a non-conductor), a semiconductor, and a conductor. The substrate 110 may also include a metal, a conductive oxide, or a conductivity nitride. The substrate 110 may include any one of an oxide, a nitride, or an oxynitride of a metal chosen from Al, Ba, Be, Ca, Cr, Cu, Cd, Dy, Ga, Ge, Hf, In, Lu, Mg, Mo, Ni, Rb, Sc, Si, Sn, Ta, Te, Ti, W, Zn, Zr, and Yb, and a magnesium fluoride, but it is not limited thereto.

Preferably, the substrate 110 may have preferred orientation. The preferred orientation of the substrate 110 may affect preferred orientation of the thin metal film 120 to be formed on the substrate 110.

The thin metal film 120 may be formed on the substrate 110. The thin metal film 120 may be formed to be grown in a 2D continuous thin film from the beginning.

A metal usually grows in 3D particles, instead of in a 2D continuous thin film on the substrate 110 due to its own low wettability. However, such growth behavior of the metal may be controlled by adjusting preferred orientation of the metal which is formed in the beginning according to the present disclosure.

The thin metal film 120 according to an embodiment of the present disclosure may include Ag or an Ag alloy. Not only (111) face of Ag or the Ag alloy generally grows but also the other faces thereof grow in the beginning stage in the view of preferred orientation. Then, the (111) face of Ag or the Ag alloy grow more as a thickness of Ag or the Ag alloy becomes thicker. Thus, it can be controlled for the (111) face of Ag or the Ag alloy to be grown from the beginning, compared to the other faces by changing such growth behavior.

The thin metal film 120 having (111) growth orientation is favorable in forming a continuous thin film with fast initial growth. On the other hand, the thin metal film substrate of the present disclosure has relatively higher ratio of (111) face of the thin metal film to the whole crystal faces which decreases as a thickness of the thin metal film increases, compared to a conventional thin metal film of which the ratio increases as a thickness of the thin metal film increases. Accordingly, the thin metal film substrate of the present disclosure shows a completely contrary trend to the conventional ones so that a continuous thin film can be formed in a relatively thin thickness.

Degree of preferred orientation (p (111)) of the (111) face of the thin metal film 120 may be 1.6 or more, but it is not limited thereto. According to an embodiment of the present disclosure, a continuous thin film having high degree of preferred orientation of the (111) face may be formed in a relatively thin thickness. When a thickness of the thin metal film is 10 nm or less, p(111) becomes 1.6 or more to form an initial continuous thin film, but it is not limited thereto.

l(111)/l(200) Of the thin metal film 120 may be 10 or more, but it is not limited thereto. According to an embodiment of the present disclosure, the continuous thin film may be formed due to high ratio of l(111)/l(200) when the thickness of the thin metal film 120 is relatively thin. When a thickness of the thin metal film is 10 nm or less, l(111)/l(200) may be 10 or more to form an initial continuous thin film, but it is not limited thereto.

When a thickness of the thin metal film 120 is 10 nm or more, degree of preferred orientation (p (111)) of the (111) face of the thin metal film 120 may be 1.7 or less, but it is not limited thereto. When the thickness of the thin metal film 120 is 10 nm or more, p(111) may become lower than the conventional thin metal film to rapidly grow a continuous thin film with a desired thickness due to predominant vertical growth of the thin metal film 120.

When the thickness of the thin metal film 120 is 10 nm or more, l(111)/l(200) of the thin metal film may be 12 or less, but it is not limited thereto. When the thickness of the thin metal film is 10 nm or more, p(111) may become lower than the conventional thin metal film to rapidly grow a continuous thin film with a desired thickness due to predominant vertical growth of the thin metal film 120.

The thickness of the thin metal film 120 may be in a range of from more than 0 nm to 40 nm, preferably from more than 0 nm to 24 nm, more preferably from more than 0 nm to 14 nm, still more preferably from more than 0 nm to 12 nm, still more preferably from more than 0 nm to 10 nm, and the most preferably from more than 0 nm to 8 nm, but it is not limited thereto. The thin metal film 120 may be preferably formed not to deteriorate transparency.

Surface roughness of the thin metal film 120 may be in a range of from more than 0 nm to 0.8 nm, but it is not limited thereto. The thin metal film 120 according to an embodiment may grow in a 2D continuous thin film due to high ratio of the (111) face to the whole crystal faces so that surface roughness may be lowed even though the thickness of the thin metal film 120 is thin.

The thin metal film 120 may be formed by a physical vapor deposition (PVD) using a process gas including N₂. The thin metal film 120 may thus include nitrogen. When the thickness of the thin metal film 120 is 10 nm or less, nitrogen content of the thin metal film 120 may be 20% or less, but it is not limited thereto.

The initial (111) face growth behavior of Ag may be strengthened with preferred orientation of the substrate 110. The substrate 110 may include zinc oxide (ZnO). The zinc oxide (ZnO) is known to have better wettability of noble metals, compared to polymer, glass, and Si wafer. The zinc oxide (ZnO) has mainly (002) face growth orientation which is identical growth orientation to the (111) face of Ag. Accordingly, the thin metal film 120 is controlled to grow in the orientation corresponding to the preferred orientation of the substrate 110 during the initial growth.

In the present disclosure, Ag is used for the thin metal film 120, but it is not limited thereto. For example, the thin metal film 120 may include any metal having the above-mentioned preferred orientation such as an Ag alloy and Ni.

FIG. 2 is a diagram illustrating internal configuration of a thin metal film substrate according to another embodiment of the present disclosure.

Referring to FIG. 2(A), a thin metal film substrate according to a second embodiment may further include an intermediate layer 130 in addition to the substrate 110 and the thin metal film 120. Referring to FIG. 2(B), a thin metal film substrate according to a third embodiment may further include a protecting layer 140 in addition to the substrate 110 and the thin metal film 120. Referring to FIG. 2(C), a thin metal film substrate according to a fourth embodiment may include the substrate 110, the intermediate layer 130, the thin metal film 120 and the protecting layer 140. For example, the thin metal film substrate may be a transparent conductivity thin film formed in a structure of transparent inorganic material layer-thin metal film-transparent inorganic material layer.

The intermediate layer 130 may be formed between the substrate 110 and the thin metal film 120. The intermediate layer 130 may be formed of any one chosen from zinc oxide (ZnO), ITO (Indium Tin Oxide), IZO (Indium Zinc Oxide), AZO (Al-doping Zinc Oxide), GZO (Ga-doping Zinc Oxide), IGZO, ATO, and TiO₂, but it is not limited thereto. The intermediate layer 130 may be formed transparently by a physical vapor deposition on the substrate 110 to have a thickness of 20 to 200 nm. The intermediate layer 130 may be formed to keep the transparency of the substrate 110 and improve electrical conductivity.

Preferably, the intermediate layer 130 may include a material having good metal wettability. The intermediate layer 130 may replace the function of the substrate 110. The intermediate layer 130 may include a material such as zinc oxide (ZnO) having preferred orientation to affect growth characteristics of the thin metal film 120 when the substrate 110 is glass or a polymer.

The protecting layer 140 may be formed on the thin metal film 120 to prevent oxidation and physical damages of the thin metal film 120. The protecting layer 140 may be formed of any one chosen from zinc oxide (ZnO), ITO, IZO, AZO, GZO, IGZO, ATO, and TiO₂, but it is not limited thereto. The protecting layer 140 may be formed transparently by a physical vapor deposition on the substrate 110 to have a thickness of 20 to 200 nm. The protecting layer 140 may be formed to keep the transparency of the substrate 110 and improve electrical conductivity. The protecting layer 140 may be formed of zinc oxide (ZnO).

The intermediate layer 130 and the protecting layer 140 may be formed using the same or different material.

The thin metal film substrate of the present disclosure may be formed in various combinations of the metal thin film 120, the intermediate layer 130 and the protecting layer 140 on the substrate 110 as shown in FIG. 2.

The thin metal film substrate of the present disclosure may have 30 Ω/sq or less of superior sheet resistance, but it is not limited thereto.

The thin metal film substrate of the present disclosure may have flex resistance for bending diameter of 10 mm or less, but it is not limited thereto.

The thin metal film substrate of the present disclosure may have 85% or more of light transmittance, but it is not limited thereto. The thin metal film substrate of the present disclosure may have 90% or more of light transmittance in the visible light region (400-800 nm), but it is not limited thereto.

As described above, the thin metal film substrate of the present disclosure may be widely used for articles in various application fields since the thin metal film can be formed in a 2D continuous thin film from the beginning to provide excellent electrical conductivity and light transmittance.

The thin metal film substrate may be used for articles such as a transparent electrode for displays, a polarizing plate, a transparent electrode for solar cells, a low-emission coating, a transparent electrode for heating, or a metal micro-electrode for semiconductors, but it is not limited thereto.

FIG. 3 is a flowchart illustrating a method for forming a thin metal film substrate according to an embodiment of the present disclosure.

In step 210, the substrate 110 is prepared. The substrate 110 may be formed to include zinc oxide (ZnO) when the intermediate layer 130 is not formed. The substrate 110 may be formed of various materials without any limitation as described above.

In step 220, an amount of a process gas to be used for a sputtering process may be determined.

In step 230, the thin metal film 120 may be formed.

The thin metal film 120 according to an embodiment of the present disclosure may be formed by sputtering Ag through the sputtering process and the process gas may include Ar and N₂.

An amount of the process gas may be determined for the thin metal film to have preferred orientation corresponding to the preferred orientation of the substrate during the initial growth. The preferred orientation in the present disclosure means increase or decrease of a ratio of at least one crystal face to the entire crystal faces, not forming to an identical orientation of the entire crystal faces.

Preferred orientation of the metal may be expected in accordance with an amount of the process gas through experiments or theoretical calculation. Thus, the amount of the process gas may be determined to correspond to the preferred orientation.

When the thin metal film 120 is deposited, the process gas only including Ar may be used but N₂ may be also additionally injected. The nitrogen may change plasma environment of the sputtering process, but do not affect conductivity and optical transmittance of the thin metal film 120. In the N₂ injection process, trace amount of NOₓ may be included.

The N₂ injection may induce (111) face growth during the initial growth of Ag. This growth behavior allows growing the thin metal film 120 in a 2D continuous thin film even at a very thin thickness.

The N₂ injection may also allow growing the thin metal film 120 to have a preferred orientation corresponding to the preferred orientation of the substrate 110. The N₂ may also affect structure of the final product. The thin metal film 120 to be deposited may be dependent on the preferred orientation of the substrate 110 to have a preferred orientation corresponding to the preferred orientation of the substrate 110.

On the other hand, the N₂ may bond actively with the metal in the initial sputtering process so that nitrogen (N₂) content may vary with the thickness of the thin metal film. When the thickness of the thin metal film is 10 nm or less, nitrogen content of the thin metal film may be 20% or less, preferably 10% or less, but it is not limited thereto.

The process gas of the sputtering process may be Ar and N₂ in a ratio of 45:2 to 35, preferably 45:4 to 16, but it is not limited thereto. (111) face growth may be induced during the initial growth of Ag in this range.

The ratio of (111) face of the thin metal film to the whole crystal faces may decrease as the thickness of the thin metal film increases due to control of the process gas as described above.

Preferred orientation of the thin metal film 120 may be more dependent on the substrate 110 when the metal includes Ag and the substrate 110 includes zinc oxide (ZnO).

The thin metal film 120 may be formed at a temperature of 100° C. or less or may be also formed preferably at room temperature.

The intermediate layer 130 may be formed by a physical vapor deposition using zinc oxide (ZnO) as a sputtering target.

The intermediate layer 130 may be formed initially by injecting Ar gas into a vacuum chamber at an initial degree of vacuum of 3×10⁻⁶ Torr or less and then by applying 200 W [symbol] | RF power to 4 inch zinc oxide (ZnO) sputtering target at a degree of operation vacuum of 3×10⁻³ Torr.

Deposition conditions of the intermediate layer 130 are as follows.
Sputtering target: zinc oxide (ZnO) (4 inch)
Operation gas: Ar (100%, 45 sccm)
Degree of operation vacuum: 3× 10⁻³ Torr
RF Power: 200 W
Coating speed: 0.12 nm/sec
Property: n-type

The thin metal film 120 according to an embodiment may be formed by a physical vapor deposition with Ag as a sputtering target.

Deposition conditions of the thin metal film 120 are as follows.
Sputtering target: Ag (4 inch)
Process gas: Ar:N₂ (45: 0-32 sccm)
Degree of operation vacuum: 3×10⁻³ Torr
DC Power: 50 W
Temperature (° C.): Room temperature
Coating speed: ˜0.18-˜0.16 nm/sec

The protecting layer 140 may be formed of the same material used for the intermediate layer 130 and conditions for the sputtering process and the deposition may be the same as well.

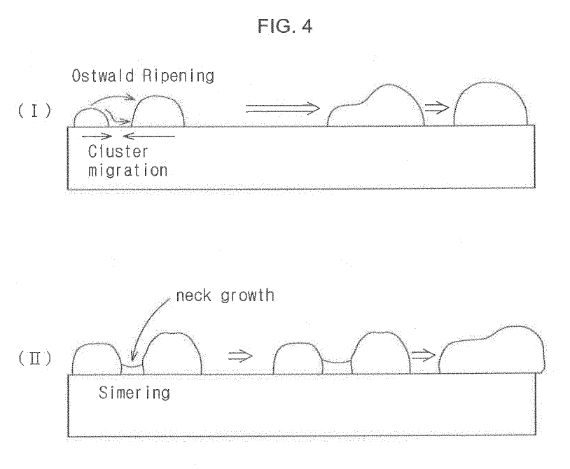

FIG. 4 illustrates diagrams comparing growth pattern (I) of a general metal and growth pattern (II) of a metal according to an embodiment of the present disclosure.

FIG. 4(I) is growth pattern of a general metal. The metal formed of micro-particles may interconnect with each other and grow through the Ostwald ripening to cluster migration as shown in FIG. 4(I). This grow behavior does not satisfy to form in a 2D continuous thin film during the initial growth. Arrows on the substrate in FIG. 4 do not mean actual particles' migration but means growth of the particles with time at the same position.

FIG. 4(II) is growth pattern of a metal according to the present disclosure. Growth in accordance with the Ostwald ripening to cluster migration is not prevented from the beginning but growth through interconnections between adjacent particles, of which migration is prevented, is exhibited.

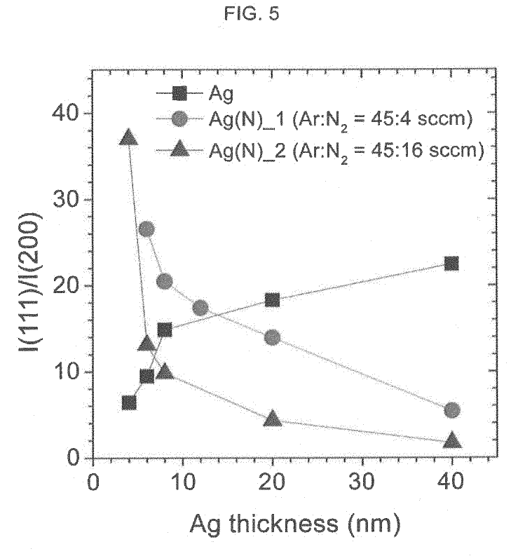

FIG. 5 is a graph illustrating preferred orientation of a thin metal film according to an embodiment of the present disclosure depending on an amount of a process gas and a thickness of the thin metal film.

FIG. 5 illustrates the results when the substrate 110 is zinc oxide (ZnO) and the thin metal film 120 is Ag and the amount of Ar and N₂ of the sputtering process gas is 45:0 sccm, 45:4 sccm, and 45:16 sccm, respectively.

According to nominal thickness-based analysis, when only Ar is used for the process gas, l(111)/l(200) increases as the thickness of the thin metal film 120 increases.

On the other hand, when Ar and N₂ are used for the process gas. (111) face increases rapidly from the initial growth but decreases rapidly as the thickness of the thin metal film 120 increases, which is conflicting result shown with pure Ag.

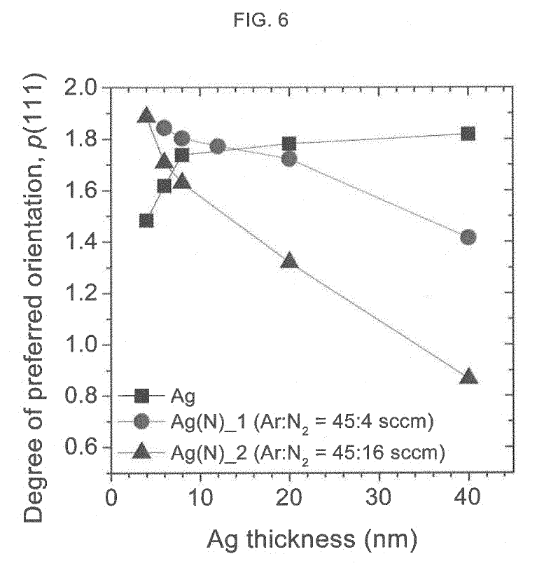

FIG. 6 is a graph illustrating degree of preferred orientation of a thin metal film according to an embodiment of the present disclosure depending on an amount of a process gas and a thickness of the thin metal film.

Degree of preferred orientation of the (111) face represents growth degree of the (111) face. When p(111)>1, it represents main growth of the (111) face, while when p(111)<1, it represents growth of the rest surfaces, except the (111) face.

FIG. 6 illustrates the results when the substrate 110 is zinc oxide (ZnO) and the thin metal film 120 is Ag and the amount of Ar and N₂ of the sputtering process gas is 45:0 sccm, 45:4 sccm, and 45:16 sccm, respectively.

According to nominal thickness-based analysis, when only Ar is used for the process gas, the (111) face increases as the thickness of the thin metal film 120 increases which is similar to the result shown in FIG. 5.

On the other hand, when Ar and N₂ are used for the process gas, (111) face increases from the initial growth but decreases as the thickness of the thin metal film 120 increases.

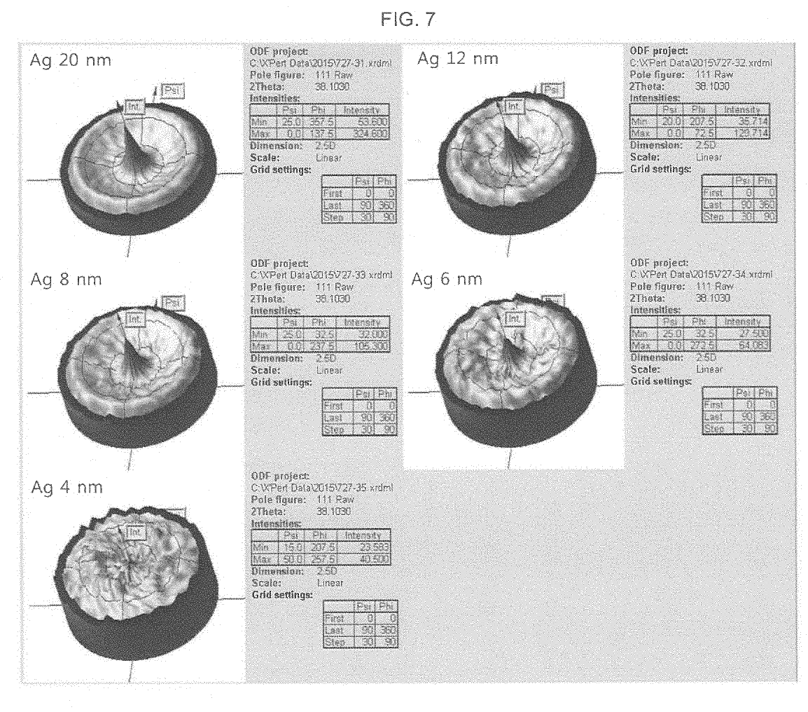

FIG. 7 to FIG. 9 are Pole figures illustrating Psi rocking curves relating to preferred orientation depending on an amount of a process gas and a thickness of the thin metal film. Degree of growth of Ag(111) may be determined based on the thickness through these measurements.

Referring to FIG. 7, degree of growth of Ag(111) is low at 20 nm when pure Ag is used for the process gas.

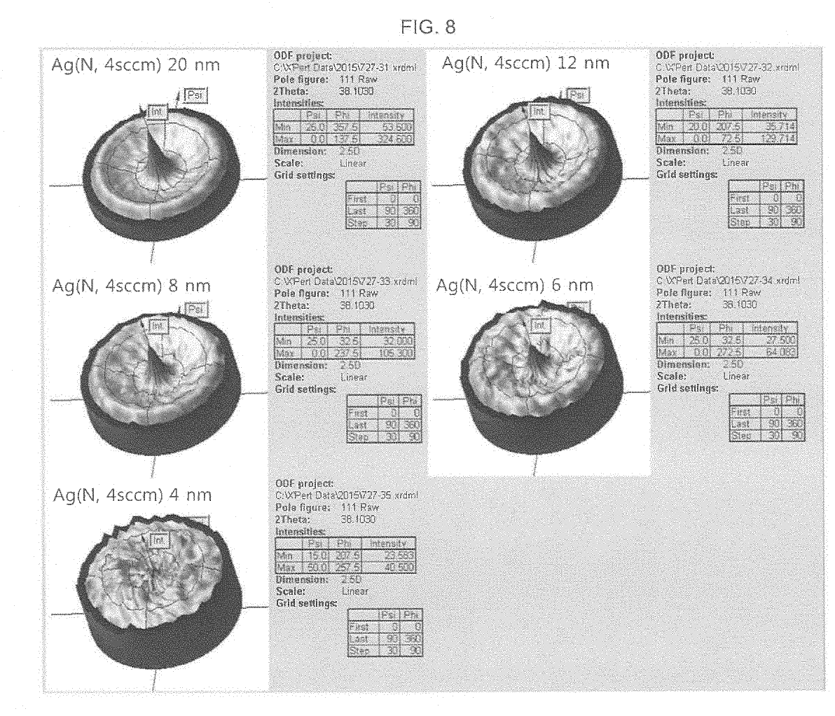

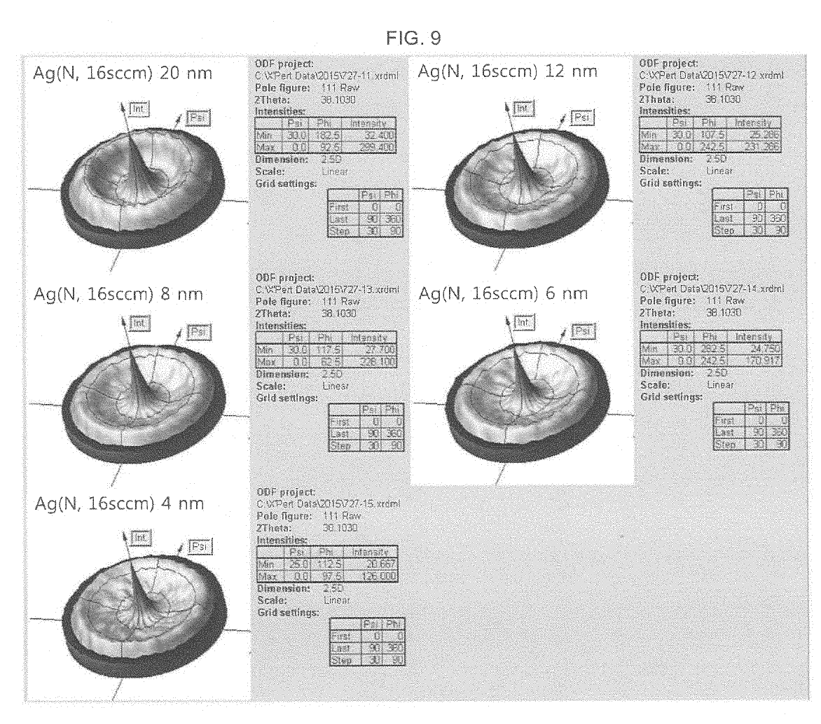

Referring to FIG. 8 and FIG. 9, the (111) face grows from the beginning and decreases as the thickness of the thin metal film 120 increases when the thickness of the thin metal film 120 increases.

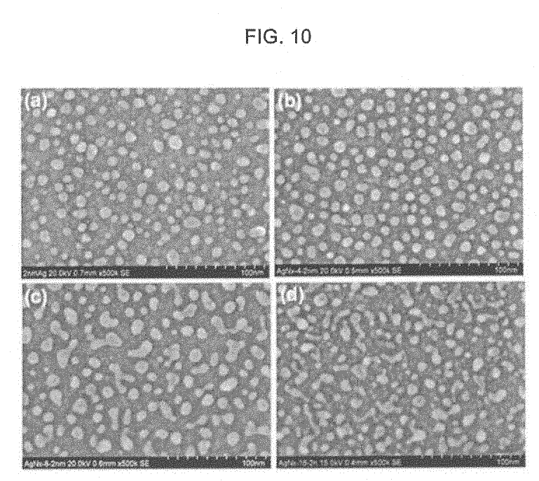

FIG. 10 to FIG. 15 are FE-SEM (Model S-5500, Hitachi Co) images of a thin metal film according to an embodiment of the present disclosure depending on an amount of a process gas.

FIG. 10 illustrates the results when the substrate 110 is zinc oxide (ZnO) and the thin metal film 120 is Ag and the amount of Ar and N₂ of the sputtering process gas is 45:0 sccm ((a) of FIG. 10), 45:4 sccm ((b) of FIG. 10), 45:8 sccm ((c) of FIG. 10) and 45:16 sccm ((d) of FIG. 10), respectively.

The thin metal film 120 in (a) of FIG. 10 is before the thin metal film 120 is formed which exhibits growth property before forming in a 2D continuous thin film. Here, a nominal thickness of the metal is 2 nm.

Referring to FIG. 10, when only Ar is used for the process gas, particles grow individually without interconnected with each other as shown in (a) of FIG. 10. On the other hand, when Ar and N₂ are used for the process gas, particles are interconnected with each other to form a 2D continuous thin film as shown in (b) to (d) of FIG. 10.

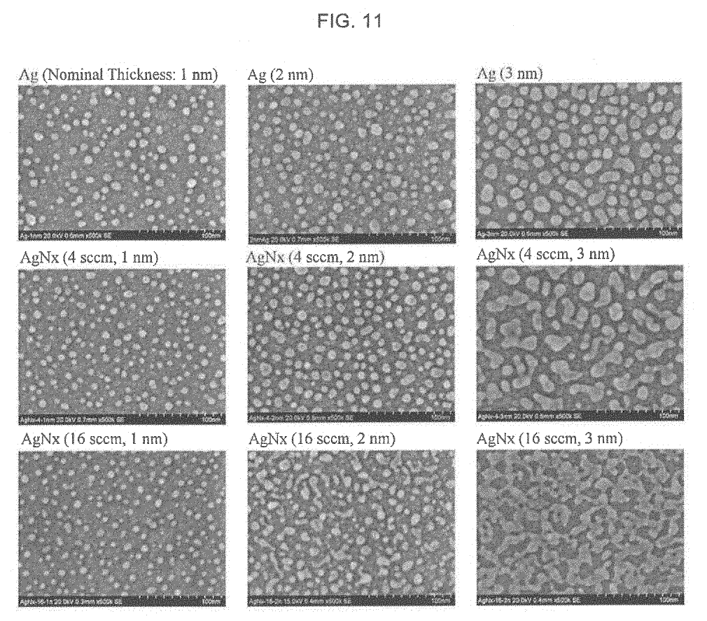

FIG. 11 to FIG. 15 illustrate morphology properties of Ag and Ag(N) deposited in different thicknesses on a ZnO thin film having a thickness of 20 nm when a ratio of Ar:N₂ gas, which is injected in the sputtering process of Ag, is controlled to be 50 sccm:0 sccm (for Ag), 50 sccm:4 sccm (for Ag(N) (4 sccm)), and 50 sccm:16 sccm (for Ag(N) (16 sccm).

Referring to FIG. 11, it is noted that in Ag and Ag(N) (4 sccm) in a thickness of 2 nm, general and independent polygon-shaped metal clusters (very small particles grown through nucleation) are formed, while in Ag(N) (16 sccm), the polygon-shaped structures are disappeared but random clusters and neck-like bridges connecting these clusters are formed instead. In Ag(N) (4 sccm) in a thickness of 3 nm, random clusters are shown. However, when Ag(N) (4 sccm) and Ag(N) (16 sccm) are compared, it is shown that Ag(N) (16 sccm) covers the ZnO surface more which exhibits high wettability and dispersion.

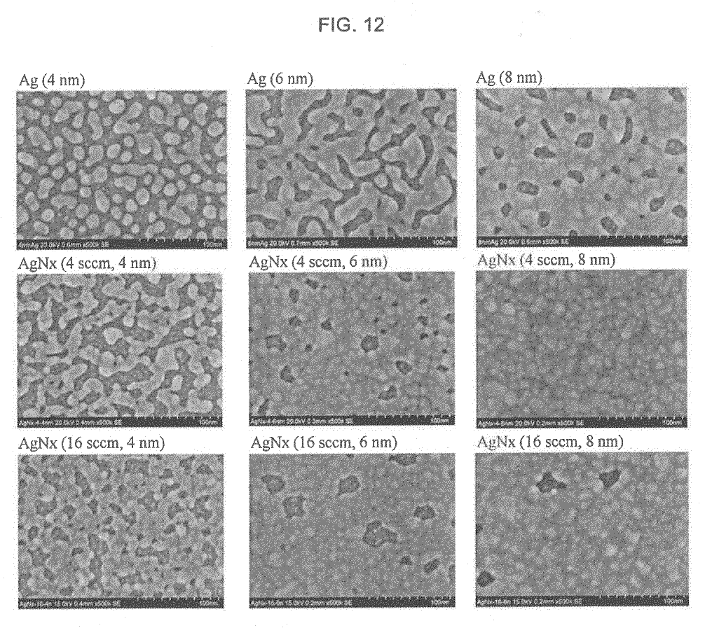

Referring to FIG. 12, in Ag, the random clusters are shown in a thickness of about 6 nm. In the same thickness, Ag(N) (4 sccm) and Ag(N) (16 sccm) show much higher wettability so that most of the ZnO surface is covered with Ag(N).

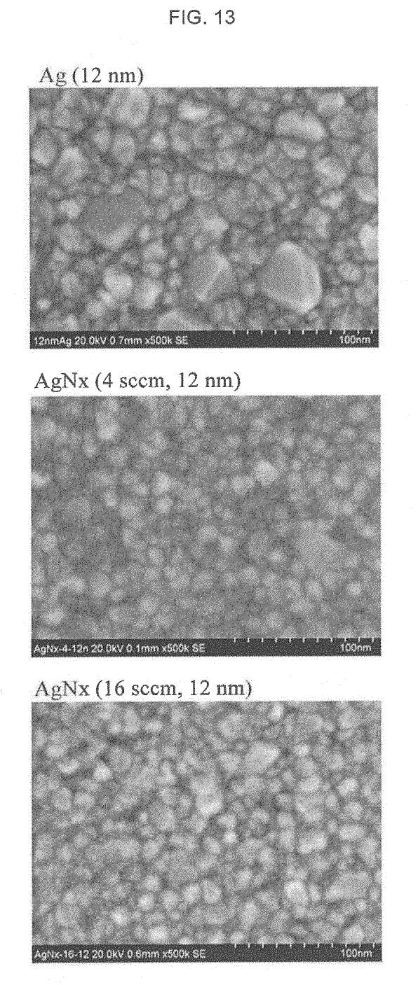

Referring to FIG. 13, when the thickness is increased a lot as shown in a thickness of 12 nm or more, the ZnO surface is completely covered by Ag but coarse Ag particles are formed, while in Ag(N), relatively small particles are formed.

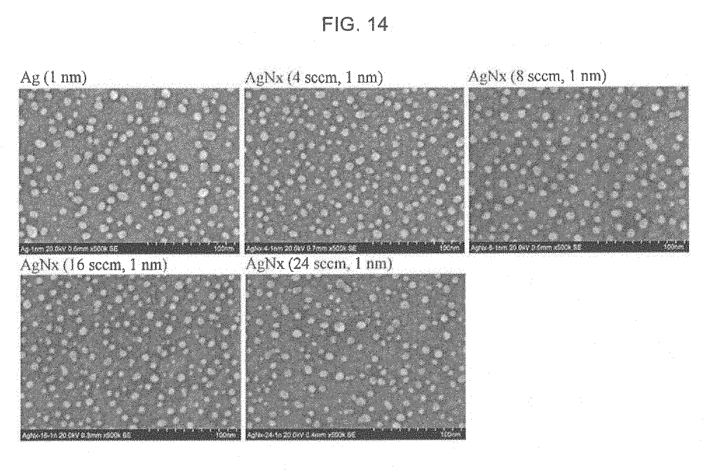

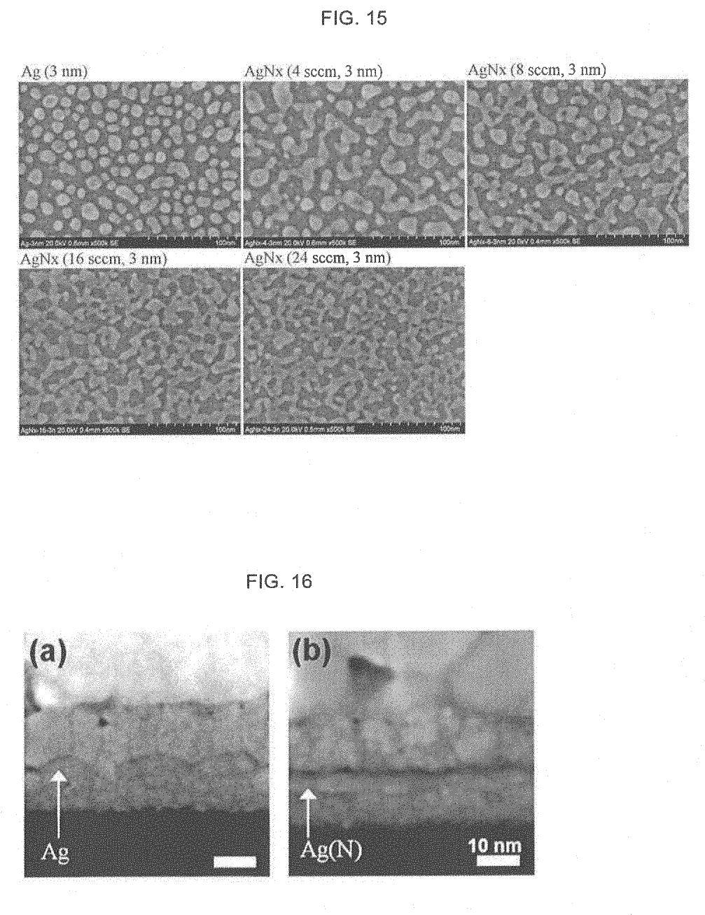

FIG. 14 and FIG. 15 illustrate evolution process of initial clusters depending on nitrogen content from 0 sccm to 24 sccm in Ag(N).

Referring to FIG. 14, there is no significant difference between pure Ag and N-doped Ag and between low N-doping level and high N-doping level in a thickness of 1 nm. It is noted that densities of fine Ag nuclei which are stabilized through nucleation are similar.

Referring to FIG. 15, there is significant difference between pure Ag and N-doped Ag in a thickness of 3 nm. The pure Ag is distributed in still independent polygon-shaped cluster forms on the ZnO surface but coverage of the ZnO surface is still low by Ag. However, as nitrogen content increases in Ag(N), interconnections between clusters become activated and the cluster forms become irregular and thus coverage of the ZnO surface is high by Ag(N).

The thickness of pure Ag is needed to be thicker to show such morphology properties of Ag(N) to increase the size of clusters, lower surface energy of the clusters, improve interfacial adhesion with ZnO and prevent migration of the clusters.

FIG. 16 illustrates FE-SEM images of the thin metal film substrate depending on the process gas.

FIG. 16 illustrates a sectional view of Ag formed in a thickness of 6.5 nm between the intermediate layer 130 and the protecting layer 140 in which the intermediate layer 130 is formed of zinc oxide (ZnO) and the protecting layer 140 is also formed of zinc oxide (ZnO) on the substrate 110.

When Ar and N₂ are used for the process gas ((b) of FIG. 16), surface roughness is relatively lower than when only Ar is used for the process gas ((a) of FIG. 16). When Ar and N₂ are used for the process gas ((b) of FIG. 16), it is noted that a continuous thin film is formed.

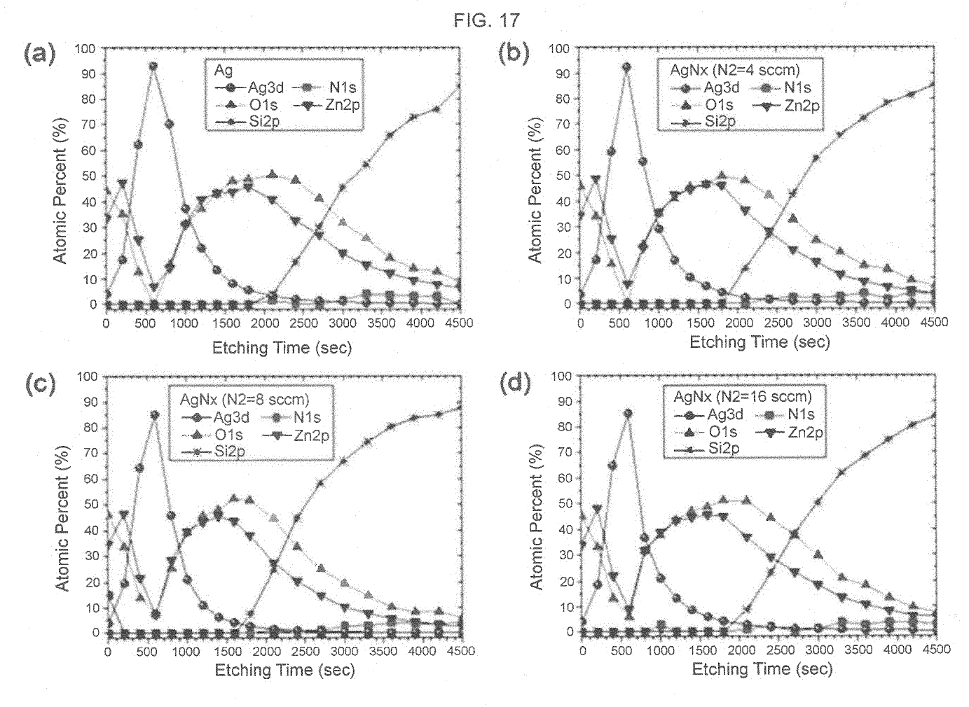

FIG. 17 illustrates diagrams of compositional analyses of a thin metal film substrate according to an embodiment of the present disclosure.

FIG. 17 illustrates XPS depth profiling thin metal film substrate of the structure in which the intermediate layer 130 is formed of zinc oxide (ZnO) with a thickness of 20 nm on the substrate 110 which is formed of Si wafer and the protecting layer 140 is formed of zinc oxide (ZnO) with a thickness of 5 nm and a Ag metal layer is formed with a thickness of 24 nm between the intermediate layer 130 and the protecting layer 140. Here, each amount of Ar and N₂ of the process gas is 45:0 sccm ((a) of FIG. 17), 45:4 sccm ((b) of FIG. 17), 45:8 sccm ((c) of FIG. 17) 45:16 sccm ((d) of FIG. 17).

The thin metal film substrate is performed for compositional analysis till only Si wafer is detected while eliminating through ion etching. As shown in (a) to (d) of FIG. 17, nitrogen (N₂) is not detected at 600 sec of etching time where Ag composition is the most. However, the thin metal film 120 may include 1% or less of nitrogen (N₂) when the detection limit of XPS is considered since the inclusion of the nitrogen cannot be ruled out completely.

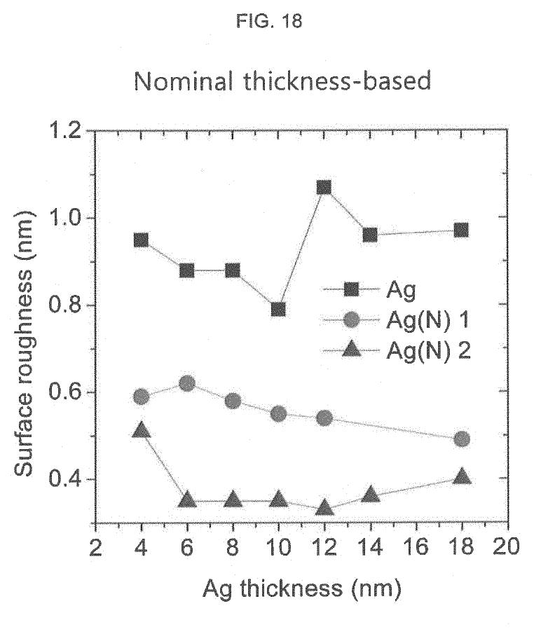

FIG. 18 is a graph comparing surface roughness of a thin metal film substrate according to an embodiment of the present disclosure depending on an amount of a process gas. Surface roughness is determined by using XRR (X-Ray Reflectivity, Model: Empyrean, PANalytical).

When Ar:N₂=45:4 sccm or Ar:N₂=45:16 sccm are used for the progress gas, surface roughness becomes lowered compared to when only Ar is used.

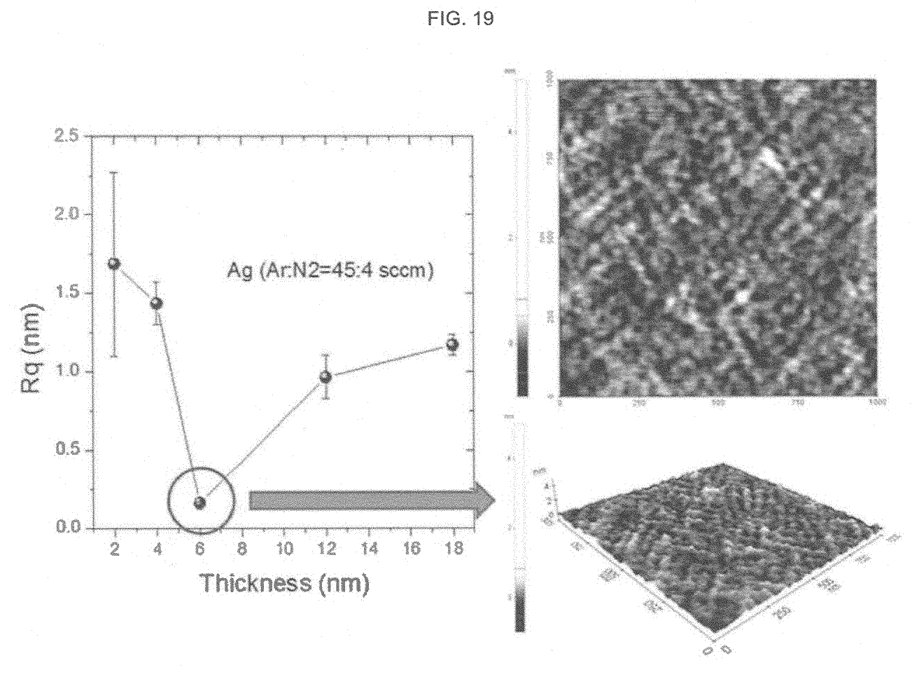

FIG. 19 is a graph comparing surface roughness of a thin metal film substrate according to an embodiment of the present disclosure depending on a thickness of the thin metal film substrate. The surface roughness is determined with AFM. When Ar:N₂=45:4 sccm is used for the process gas and the thin metal film 120 is deposited in a thickness of 6 nm, the lowest surface roughness is shown.

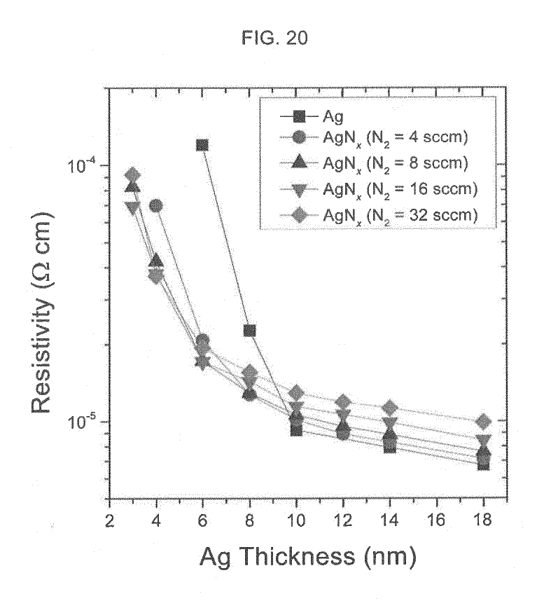

FIG. 20 is a graph comparing resistivity of a thin metal film substrate according to an embodiment of the present disclosure depending on an amount of a process gas.

FIG. 20 illustrates resistivity determined with structures of ZnO(20 nm)/Ag/ZnO(20 nm) and ZnO(20 nm)/Ag(N)/ZnO(20 nm) using a Four-point probe system (MCP-T600, Mitsubishi Chemical Co.).

Referring to FIG. 20, it is noted that resistivity is lower when Ar and N₂ are used for the process gas than that is when only Ar is used. Particularly, when the thickness is thin, the difference is more significant.

The result proves that N-doping accelerates formation of the continuous thin film of Ag since decrease in the resistivity is in reverse proportion to increase in the conductivity due to the formation of the continuous thin film. It is noted that this phenomenon reaches the saturation at Ag(N), 8-16 sccm, and then increase in N leads increase in the resistivity when Ag is formed in the continuous thin film (when the thickness is 10 nm or more).

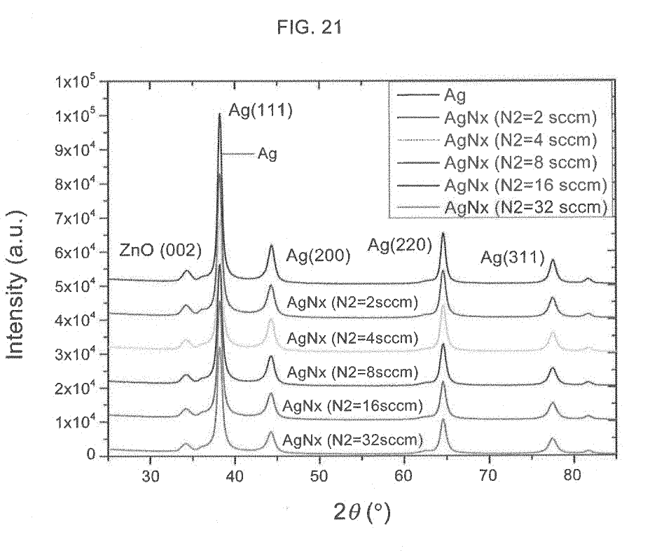

FIG. 21 is a graph illustrating whether independent AgN phase is present or not in Ag(N) through 2 theta scanning of a thin metal film according to an embodiment of the present disclosure.

Referring to FIG. 21, it is noted that all Ag peaks are shown in Ag(N) and the deposited Ag(N) is an Ag metal. It is also noted that crystallinity is changed since peak intensities and FWHM values are changed due to N inclusion.

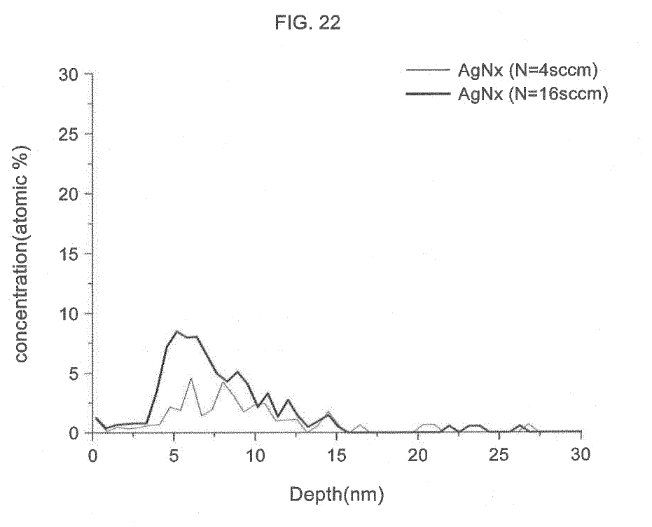

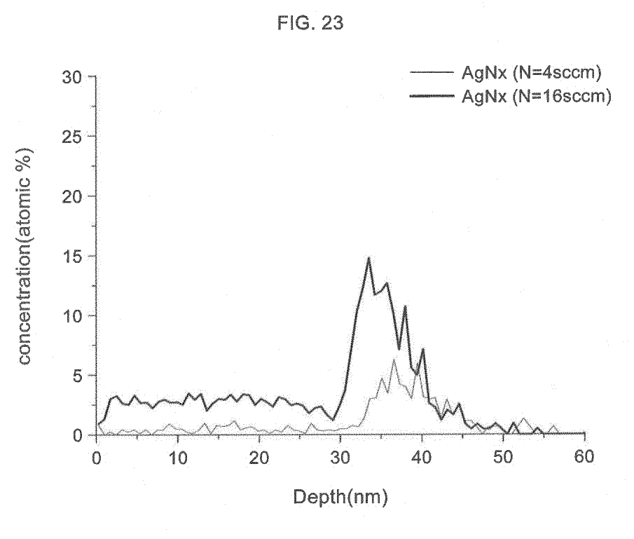

FIG. 22 and FIG. 23 are graphs illustrating SIMS analyses to detect residue N in Ag(N). It is noted that residual quantity of N is detected with the SIMS analysis and Ag(111)/Ag(200) varies with N content.

The SIMS analysis is performed at the Korea Basic Science Institute, Busan Center and analysis equipment and conditions are summarized in Table 1.

TABLE 1

| Analysis | CAMECA IMS-6f Magnetic Sector SIMS | | | | |
|---|---|---|---|---|---|
| Equipment | | | | | |
| Analysis | Cs⁺ Gun, Impact Energy: 5 keV, Current 10 nA, Raster Size: 200 μm × 200 μm Analysis Area: | | | | |
| Conditions | 60 μm(Φ), Detected Ion: ¹³³Cs¹²C⁺, ¹³³Cs¹⁴N⁺, ¹³³Cs¹⁶O⁺, ¹³³Cs²⁸Si⁺, ¹³³Cs¹⁰⁷Ag⁺ | | | | |
| Sample | Sample name | #02 | #03 | #04 | #05 |
| | Sample | AgNx(20 nm) | AgNx(100 nm) | AgNx(20 nm) | AgNx(100 nm) |
| | condition | (N = 4 sccm) | (N = 4 sccm) | (N = 16 sccm) | (N = 16sccm) |

FIG. 22 illustrates Ag(N) with the thickness of 20 nm formed on a Si wafer and FIG. 23 illustrates Ag(N) with the thickness of 100 nm formed on a Si wafer.

Referring to FIG. 22, when Ag(N)_1 (Ar:N₂=45:4 sccm), after N atomic % (concentration) reaches about 5% in an initial thin film, it is decreased and maintained at 1% or less.

Referring to FIG. 23, when Ag(N)_2 (Ar:N₂=45:16 sccm), after N atomic % (concentration) reaches about 5-15% in an initial thin film, it is decreased and maintained at about 2-3%.

The SIMS result which determines increase in N in the initial thin film is compared with the XRD result which determines a l(111)/l(200) ratio depending on N-injection. It is noted that the surface of Ag cluster is in a polygonal structure having several faces at the Ag initial thin film where the continuous thin film is not formed yet but individual clusters or granules are formed.

The surface of the initial Ag cluster has high surface energy to have high surface reactivity due to small cluster size. The reactivity decreases as the cluster size increases.

A large amount of N is adsorbed to the initial Ag cluster to lower surface reactivity even though barrier of the bonding energy between Ag and N is high.

Such N adsorption prevents growth of a face by inhibiting adsorption of Ag (inhibiting Ag—Ag cohesion) which reaches to the cluster.

However, the (111) face of the Ag cluster has the lowest surface energy compared to the rest faces, particularly the (200) face, and thus is the most stable so that the N adsorption is relatively inhibited. Thus, Ag (111) keeps growing compared to the other faces.

Accordingly, p(111) or l(111)/l(200) ratio rapidly increases with the injection of N₂. It is proven from FE-SEM, TEM results that the increase of p(111) lowers cluster itself surface energy and prevents 3D growth due to coalescence (or agglomeration) between the nanoscopic clusters so that the 2D continuous thin film can be formed from the stable clusters even at the thin film.

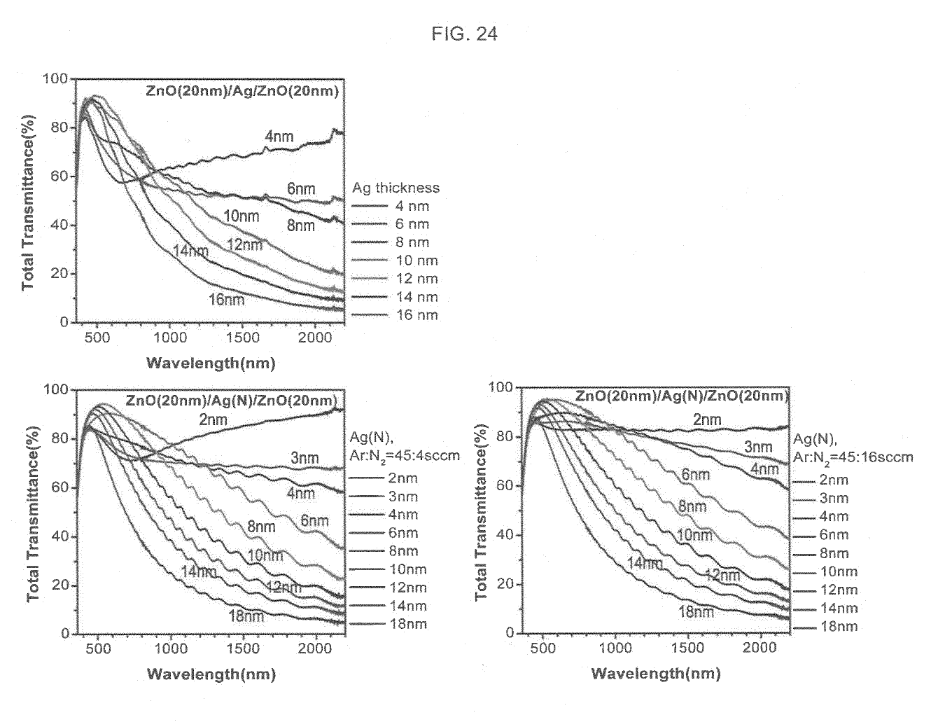

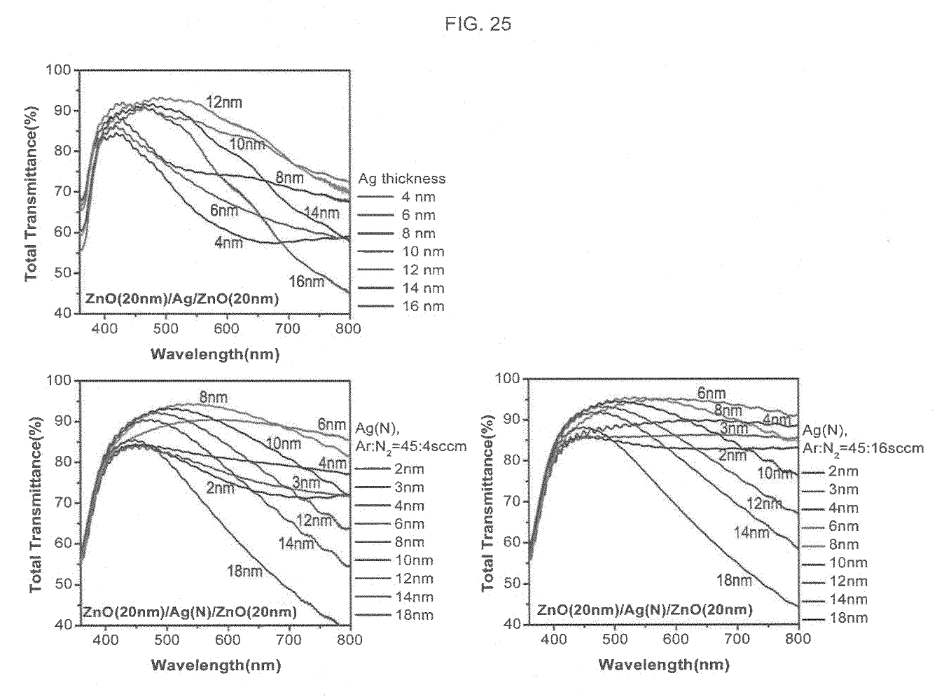

FIG. 24 and FIG. 25 are graphs illustrating optical transmittance of a thin metal film substrate according to an embodiment of the present disclosure.

It is shown from the morphology properties that the structure of ZnO/Ag(N)/ZnO (Ag(N) thin film structure formed between ZnO oxides) increases the optical transmittance (Optical transmittance UV-Visible-near infrared spectrophotometry, Cary series, Agilent technologies).

Referring to FIG. 24, it is noted that total transmittance of Ag(N), particularly Ag(N) 16 sccm is higher than that of Ag at the entire wavelengths of 400-2200 nm (Visible and near-IR region).

The optimal transmittance of Ag is observed with the thickness of 10-12 nm at the Visible region (400-800 nm), while that of Ag(N) 16 sccm is observed only with the thickness of 6 nm. From the fact that the optimal transmittance is observed even with the minimum thickness to form the continuous thin film, it is proven that the continuous thin film is formed using Ag(N) 16 sccm at the thinner thickness to improve the transmittance, compared to using Ag. This is consistent with the result that N-doping accelerates the formation of the continuous thin film.

Referring to FIG. 25 which illustrates the total transmittance only at the Visible region from FIG. 24, it further proves that light transmittance of Ag(N) increases as N-doping increases and the maximum light transmittance is observed with the thinner thickness.

The method for preparing a thin metal film substrate according to the present disclosure allows forming the 2D continuous thin film from the beginning stage of growth so that it can be suitable for all fields which require the formation of the continuous thin film such as fields for manufacturing displays, electrodes for solar cells, heaters, semiconductors and the like.

While it has been described with reference to particular embodiments, it is to be appreciated that various changes and modifications may be made by those skilled in the art without departing from the spirit and scope of the embodiment herein, as defined by the appended claims and their equivalents. Accordingly, examples described herein are only for explanation and there is no intention to limit the disclosure. The scope of the present disclosure should be interpreted by the following claims and it should be interpreted that all spirits equivalent to the following claims fall with the scope of the present disclosure.

What is claimed is:

1. A thin metal film substrate comprising:
a substrate; and
a thin metal film comprising Ag or an Ag alloy formed on the substrate,
wherein a ratio of (111) face of the thin metal film to the whole crystal faces decreases as a thickness of the thin metal film increases.

2. The thin metal film substrate of claim 1, wherein degree of preferred orientation (p (111)) of the (111) face of the thin metal film is 1.6 or more.

3. The thin metal film substrate of claim 1, wherein l(111)/l(200) of the thin metal film is 10 or more.

4. The thin metal film substrate of claim 1, wherein when the thickness of the thin metal film is 10 nm or more, degree of preferred orientation (p (111)) of the (111) face of the thin metal film is 1.7 or less.

5. The thin metal film substrate of claim 1, wherein when the thickness of the thin metal film is 10 nm or more, l(111)/l(200) of the thin metal film is 12 or less.

6. The thin metal film substrate of claim 1, wherein a thickness of the thin metal film is in a range of from more than 0 nm to 40 nm.

7. The thin metal film substrate of claim 1, wherein surface roughness of the thin metal film is in a range of from more than 0 nm to 0.8 nm.

8. The thin metal film substrate of claim 1, wherein the substrate is a transparent polymer substrate.

9. The thin metal film substrate of claim 1, wherein the substrate includes conductive oxide or nitride.

10. The thin metal film substrate of claim 1, wherein the thin metal film substrate has 30 Ω/sq or less of sheet resistance.

11. The thin metal film substrate of claim 1, wherein the thin metal film substrate has 85% or more of light transmittance.

12. The thin metal film substrate of claim 1, further comprising an intermediate layer formed between the substrate and the thin metal film.

13. The thin metal film substrate of claim 1, further comprising a protecting layer formed on the thin metal film.

14. The thin metal film substrate of claim 1, wherein the thin metal film is doped with N₂.

15. The thin metal film substrate of claim 1, wherein when a thickness of the thin metal film is 10 nm or less, nitrogen content of the thin metal film is 20% or less.

16. The thin metal film substrate of claim 1, wherein the thin metal film is formed by a physical vapor deposition using process gases of Ar and N₂.

17. The thin metal film substrate of claim 16, wherein the process gases of Ar and N₂ are in a ratio of 45:2 to 35.

18. The thin metal film substrate of claim 1, wherein the thin metal film is formed at 100° C. or less.

19. An article comprising a thin metal film substrate of claim 1.

20. The article of claim 19, wherein the article is one chosen from a transparent electrode for displays, a polarizing plate, a transparent electrode for solar cells, a low-emission coating, a transparent electrode for heating, and a metal micro-electrode for semiconductors.
